(19) United States
(12) Patent Application Publication
(10) Pub. No.: US 2026/0332150 A1
(43) Pub. Date: Oct. 22, 2026

(54) COMPENSATING FOR DELAY MISMATCH BETWEEN DELAY STAGES OF A DELAY-LOCKED LOOP

(71) Applicant: Microchip Touch Solutions Limited, Wokingham (GB)

(72) Inventor: Pranay Prabhat, Cambridge (GB)

(21) Appl. No.: 19/468,645

(22) Filed: Feb. 3, 2026

Related U.S. Application Data
(60) Provisional application No. 63/753,783, filed on Feb. 4, 2025.

(51) Int. Cl. H03L 7/081; H03K 5/133; H03L 7/08

(52) U.S. Cl. CPC H03L 7/0818; H03K 5/133; H03L 7/0807

(57) ABSTRACT

A method may include: generating multiple phase-shifted output signals at least partially based on a reference clock signal; generating a phase error signal based at least in part on a phase difference between at least one of the multiple phase-shifted output signals and the reference clock signal; determining baseline control codes at least partially based on the phase error signal; modifying the baseline control codes at least partially based on respective adjustment values; and providing the adjusted baseline control codes to the respective delay stage to regulate respective delays of respective delay stages.

### CROSS-REFERENCE TO RELATED APPLICATIONS

This application claims the benefit under 35 U.S.C. § 119(e) of U.S. Provisional Patent Application Ser. No. 63/753,783, filed Feb. 4, 2025, the disclosure of which is hereby incorporated herein in its entirety by this reference.

### FIELD

One or more examples relate, generally, to delay-locked loops (DLLs), and, more specifically, multi-phase generators implemented utilizing delay-locked loops.

### BACKGROUND

Delay-Locked Loops (DLLs) are widely used in clock generation, synchronization, and timing applications to produce phase-aligned clock signals. A DLL is a feedback control system that adjusts the delay of an input clock signal to align with a reference clock, ensuring phase relationships between generated signals. DLLs are commonly implemented in integrated circuits for applications such as memory interfaces, data communication systems, and high-speed digital processing. Unlike phase-locked loops (PLLs), which use a voltage-controlled oscillator (VCO) to generate a new clock signal, DLLs operate by tuning delay elements, resulting in lower jitter and improved stability.

DLLs are used in high-speed digital systems, enabling precise timing adjustments for applications such as clock distribution, data recovery, and duty cycle correction. Various implementations of DLLs incorporate digital or analog control mechanisms to optimize performance for specific applications.

### BRIEF DESCRIPTION OF THE DRAWINGS

To easily identify the discussion of any particular element or act, the most significant digit or digits in a reference number refer to the figure number in which that element is first introduced.

FIG. 1 is a schematic diagram depicting a DLL system, in accordance with one or more examples.

FIG. 2 is a schematic diagram depicting a DLL system that incorporates a calibration operational mode that dynamically determines and stores adjustment values instead of relying on pre-set values, in accordance with one or more examples.

FIG. 3 illustrates an example iterative process to operate a DLL based on adjustment values, in accordance with one or more examples.

FIG. 4 is a schematic diagram of a DLL system that performs calibration using a system-level performance metric in addition to (or in place of) phase-detector lock codes, in accordance with one or more examples.

FIG. 5 is a flow diagram of an example process for operating a DLL while updating stored per-stage adjustment values during operation responsive to a system-level performance metric, in accordance with one or more examples.

FIG. 6 is a flow diagram of an example process in which incremental changes to one or more stored per-stage adjustment values are made responsive to a difference between a measured metric value and a target value, in accordance with one or more examples.

FIG. 7 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths, and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer, including a processor, is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled,” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

As used herein, the terms “assert,” “de-assert” and derivatives thereof used in reference to a pin, means, respectively, to assert or de-assert a signal associated with the pin (e.g., a signal specifically assigned to the pin or a signal to which the pin is specifically assigned, without limitation).

A potential source of error in a delay-locked loop (DLL) is delay mismatch between delay stages. Here, “delay mismatch” means differences in the delay introduced by individual delay stages due to physical variation within their respective dies. By way of example, these physical variations could be due to 2nd order transistor effects, capacitance, or routing placement. The individual delay stages are expected to introduce identical delay, but delay may be different.

Mismatch between delay stages within the DLL leads to phase errors in the generated clock signals. This results in non-uniform phase shifts between consecutive DLL outputs, impacting precision in time-sensitive applications such as power conversion and high-speed communication, without limitation.

One or more examples relate, generally, to a digitally compensated DLL. The digitally compensated DLL is designed to generate phase-shifted clock signals with high precision by addressing, via digital adjustment discussed herein, delay mismatches between individual delay stages. Digitally compensated DLLs disclosed herein may achieve sub-clock edge precision for, as non-limiting examples, power converters, motor control, and digital communication applications.

In one or more examples, the system modifies a per-stage control code by introducing a per-stage adjustment value (Δ). These per-stage adjustment values are stored in registers and applied to the control codes used to set the delay of each delay stage. The modified control code ensures each delay stage receives a uniquely tuned delay adjustment, compensating for fabrication-induced mismatches (reducing delay mismatch due to fabrication differences).

In one or more examples, a DLL controller generates a baseline control code based on the difference between a feedback clock and a reference clock of a DLL. Per-stage control codes are generated based on the baseline control code and a respective adjustment values. Each delay stage receives a per-stage control code, computed as:

C_{per-stage}=C_{baseline}+Δ [Equation 1]

where Δ is an adjustment value for a respective delay stage.

In one or more examples, the adjustment values (Δ) may be: manually set via registers (static calibration) or automatically computed via a calibration procedure that measures phase errors at different stages.

Digital compensation for on-chip variations, ensuring that each phase shift is an exact fraction of the clock period.

Auto-calibration of delay stage mismatches to enhance phase matching accuracy.

Repurposing existing Fine Delay Elements (FDEs) for static and dynamic delay adjustment.

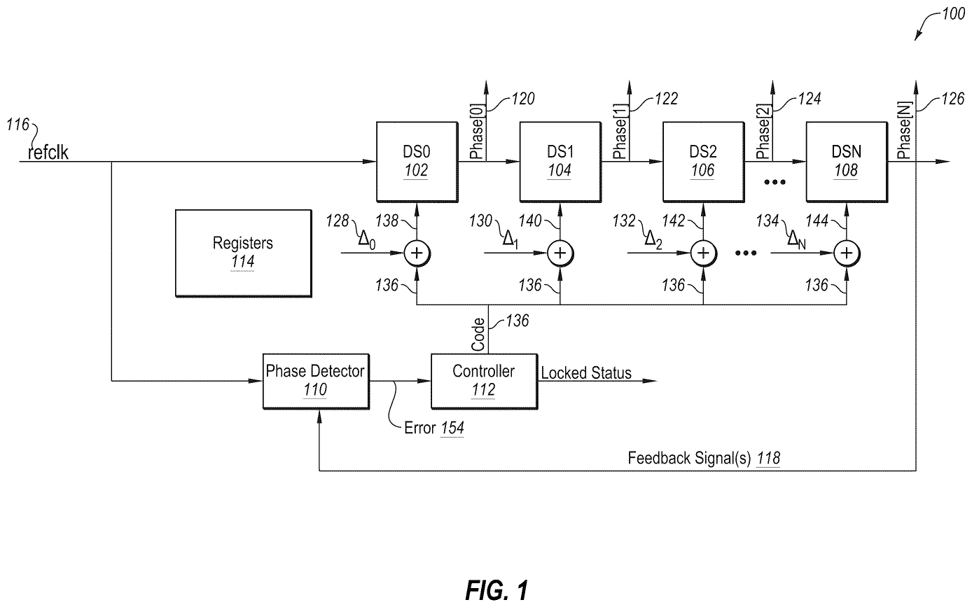

FIG. 1 is a schematic diagram depicting a DLL system 100, in accordance with one or more examples. The system compensates for delay mismatches between delay stages DS0 to DSN (where N is an integer greater than or equal to −1) to produce precise phase-shifted clock signals.

DLL system 100 generates multiple evenly spaced clock phases (e.g., phases 120, 122, 124, and 126 denoted phase[0], phase[1], phase[2], and phase[N] in FIG. 1, without limitation) from a reference clock signal 116 (refclk), while dynamically adjusting for process variations that introduce delay mismatches between delay stages 102 to 108.

DLL system 100 receives a reference clock signal 116 and propagates it through a series of delay stages (delay stage 102, delay stage 104, delay stage 106 to delay stage 108). The output of each delay stage provides a phase-shifted clock signal (phase 120, phase 122, phase 124 to phase 126). These phase shifts should be uniformly distributed across the clock period, but fabrication variations in the delay stages introduce delay mismatch.

To reduce the delay mismatch, adjustment values 128, adjustment values 130, 132 to 134 (denoted Δ0 to ΔN in FIG. 1) are dynamically added to the control code 136 (denoted “codes” in FIG. 1) sent to each delay stage. These values are determined (e.g., determined or predetermined, without limitation) and stored (e.g., stored, or pre-stored, without limitation) in registers 114 and applied to individual ones of delay stages 102 to 108 through digital adders. The phase detector 110 and controller 112 work together to monitor phase alignment and adjust the delay settings via control code 136 to achieve target phase matching.

Reference clock signal 116 is an input signal to DLL system 100 and it serves as the baseline timing reference signal for generating phase-shifted output signals. DLL system 100 produces phase-aligned versions of this reference clock signal 116. Reference clock signal 116 is fed into the first delay stage, delay stage 102. It is also fed to phase detector 110, where reference clock signal 116 is compared with one or more feedback signals 118 (e.g., feedback phase(s), without limitation), which represents the final phase output, here the Nth phase-shifted output signal 126, to detect mismatches.

Delay stages 102 to 108 are digitally controlled delay elements, such as fine delay elements (FDEs) or digitally programable delay cells, without limitation, coupled in series (output of a previous delay stage coupled to an input of the next delay stage). A respective delay stage may be a single programmable delay element that contributes some or a totality of the delay attributable to a delay stage or may be a grouping of multiple delay elements that collectively implement a larger programmable delay attributable to a delay stage.

Delay stages 102 to 108 together sequentially delay the reference clock signal 116 to produce multiple uniformly spaced phase-shifted clock signals (e.g., for precise timing applications, without limitation). Respective delay stages receive and delay the output of the preceding delay stage or reference clock signal 116 (in the case of delay stage 108) by a controlled amount to produce a phase-shifted version. Respective delay stages receive dynamically adjusted control codes (adjusted control codes 138 to 144) that modify its delay in a manner that compensates for delay mismatches, as discussed herein.

Adjusted control codes 138 to 144 are produced by combining (e.g., adding, without limitation) adjustment values 128 to 134 (received from registers 114) to baseline control code 136 sent to respective delay stages.

Phase detector 110 determines phase error in one or more feedback signals 118. Any suitable technique may be utilized to determine phase error in one or more feedback signals 118.

The one or more feedback signals 118 may include one or more of the phase-shifted output signals 120, 122, 124, or 126, and phase detector 110 may compare a respective phase-shifted output signal to reference clock signal 116 (or a target signal based on reference clock signal 116). The number of phase-shifted output signals provided as one or more feedback signals 118 may depend, as a non-limiting example, on specific operating conditions.

The phase-shifted output signal (here, the Nth phase-shifted output signal 126) may be fed to phase detector 110 as the feedback signal 118 and compared to reference clock signal 116 to determine a phase difference. A phase error signal 154 (“error 154”) indicative of this phase difference generated by phase detector 110 is provided to controller 112.

The controller 112 determines control code 136 at least based on the phase error signal from the phase detector 110. Notably, the control code determination logic of controller 112 and DLL system 100 more generally may reflect an implicit target ratio determined by feedback phase selection, that is, which phase-shifted output is selected as the feedback phases of one or more feedback signals 118. The expected condition is that the feedback signal 118 (here, the Nth phase 126) should align with a target ratio of a clock cycle delayed relative to the reference clock signal 116. Assuming no or negligible compensation for delay mismatch, the phase difference between the phase error and the target ratio can be evenly distributed across the delay stages. In most cases, the target ratio of a clock cycle delayed relative to the reference clock signal 116 will be a full clock cycle, however, the use of other target ratios does not exceed the scope of this disclosure.

In a normal DLL operational mode, the adjustment values 128 to 134 were predetermined and the DLL system 100 operates normally using the predetermined adjustment values 128-134 to respectively adjust the baseline control code 136 generated by the controller 112 to achieve and maintain lock.

In one or more examples, the adjustment values 128 to 134 may be predetermined and stored at registers 114 via external monitoring and analysis of the respective delays of the delay stages. As non-limiting examples, based on or in response to external monitoring and analysis of the respective delays of the delay stages.

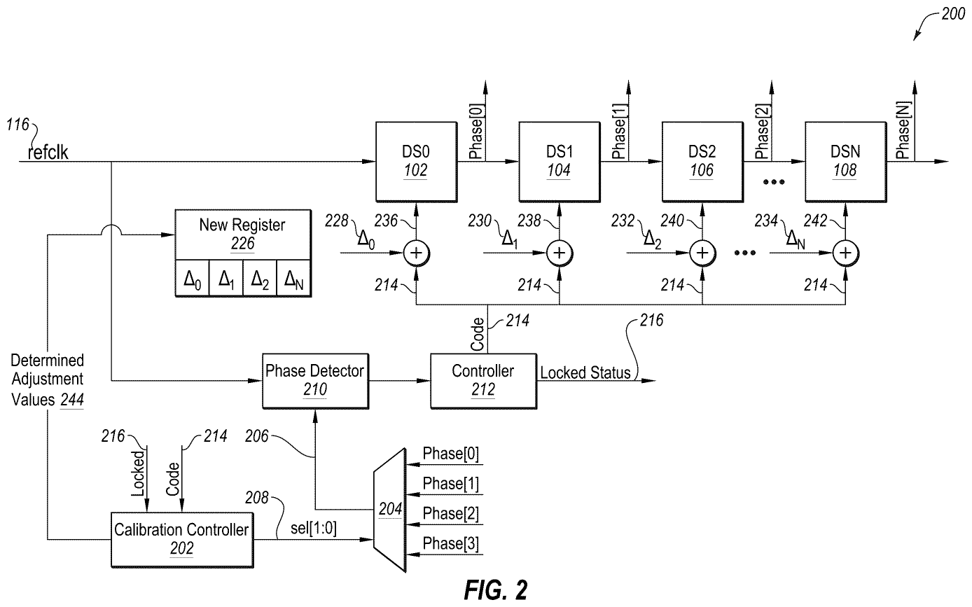

FIG. 2 is a schematic diagram depicting a DLL system 200 that incorporates a calibration operational mode that dynamically determines and stores adjustment values (Δ0, Δ1, Δ2, . . . ΔN) instead of relying solely on pre-set, fixed adjustment values, in accordance with one or more examples.

In this example, the DLL system 200 includes delay stages, a phase detector, a controller, and a register similar to DLL system 100 of FIG. 1. It also includes a calibration controller 202 and multiplexer 204 for a calibration process discussed below.

In one or more examples, the calibration controller 202 runs a calibration process whereby it iterates through different phase outputs of the delay stages to measure delay mismatches, controls the multiplexer 204 (via selection signal 208) to select different phase signals for comparison, receives locked status signals 216 from the phase detector 210, determines adjustment values (Δ0 to ΔN) based on deviations from expected phase differences (e.g., differences between measured phase difference and target ratio, without limitation), and sends the determined adjustment values 244 to the register 226 for storage as respective adjustment values 228-244.

Additionally or alternatively, the calibration controller 202 may run a calibration procedure where it measures phase error by locking onto different phases (phase outputs of the delay stages) sequentially, compares locked ones of control codes 214 to expected values (e.g., target values for locked control codes that are predetermined, without limitation), identifies deviations that indicate per-stage delay mismatch, determines adjustment values 244 based on identified deviations, and stores those determined adjustment values 244 in the registers 226.

In the case of determining the adjustment value based on control codes applied at different locking conditions, the adjustment values may be determined by, as a non-limiting example: measuring phase alignment error by analyzing control codes at multiple delay stages optionally under varying conditions, determining per-stage correction factors using a weighted sum of control code differences, and distributing phase mismatch corrections across the N delay stages based on fractions of control code differences. Each adjustment value 244 represents the correction determined (here, as a fraction of the control code difference) for a specific delay stage to achieve uniform phase spacing.

In one or more examples, information about respective ones of the delay stages 102-108 (e.g., information about delay mismatch or indicative thereof, without limitation) may be elicited by varying the DLL feedback clock (e.g., varying the selected phase 206 (which is utilized, at least in part, as a feedback clock) via control of MUX 204, without limitation) and observing the control code 214 at lock. Additionally, or alternatively, a well-defined reference clock (e.g., a well-defined version of reference clock signal 116, without limitation) may be varied to achieve the same effect. Any suitable interpolation technique may be used to exploit the same principle without exceeding the scope of this disclosure.

For N delay stages, an adjustment value Δᵢ of the i-th delay stage (where i is an integer 1 to N) can be written according to Equation 2, below, where each Δᵢ value is computed using a weighted difference of control codes, which progressively accumulate error terms from previous delay stages:

$${Δ}_{i} = \frac{1}{N} ( {W}_{0} {C}_{0} + {W}_{1} {C}_{01} + {W}_{2} {C}_{012} + … {W}_{N} {C}_{012 … N} ) \qquad [ Equation 2 ]$$

Where:

Δᵢ are adjustment value for delay stage i.

N is the total number of delay stages.

C₀ is a control code used for phase 0 locking and captures the delay mismatch up to DS0.

C₀₁ is a control code used when phase 1 is locked and captures the delay mismatch up to DS1.

C₀₁₂ is a control code used when phase 2 is locked and captures the delay mismatch up to DS2.

C_{012 . . . N} is a control code used when phase N is locked and captures the delay mismatch up to DSN.

W₀, W₁, W₂, . . . W_{N} are weighting coefficients (which weighting coefficients may be positive or negative) assigned based on the delay stage position in the sequence. These weighting coefficients determine how each control code contributes to the correction of each delay stage. The weighting coefficients increase for later delay stages, accounting for cumulative mismatch effects.

Notably, Equation 2 is a non-limiting example and corresponds to one convenient linearized form. In general, adjustment values may be determined from the locked codes C[k] by any suitable mapping—including rational (ratio-of-polynomials) expressions with numerator and denominator of order up to N—and may be implemented using lower-order approximations for efficiency, with coefficients permitted to be positive or negative. Accordingly, the invention is not limited to the form of Equation 2.

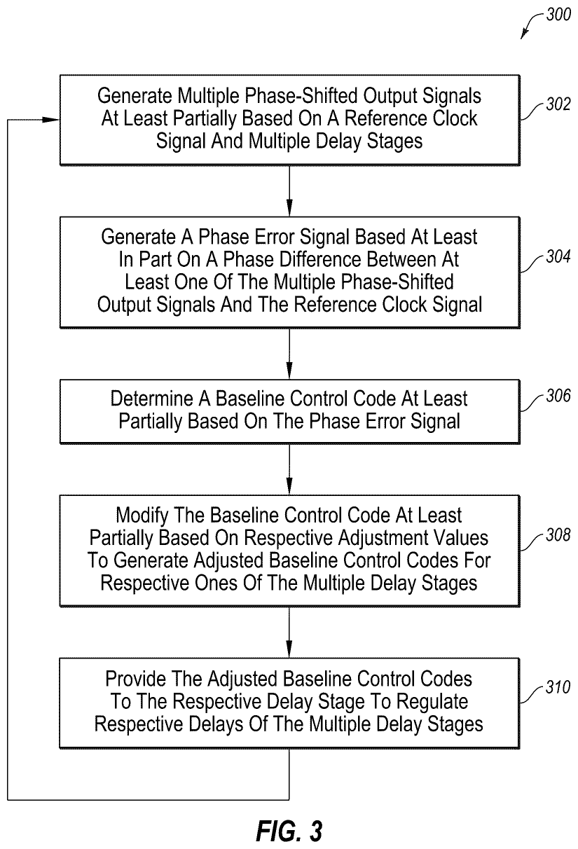

FIG. 3 illustrates an example process 300 to operate a DLL based on adjustment values, in accordance with one or more examples. Although the example processes 300 depict a particular sequence of operations, the sequence may be altered without departing from the scope of the present disclosure. For example, some of the operations depicted may be performed in parallel or in a different sequence that does not materially affect the function of the process 300. In other examples, different components of an example device or system that implements the process 300 may perform functions at substantially the same time or in a specific sequence. Some or a totality of operations of process 300 may be performed, as non-limiting examples, by DLL system 100 or DLL system 200.

According to one or more examples, process 300 may include generating multiple phase-shifted output signals at least partially based on a reference clock signal at block 302. The DLL system creates multiple phase-shifted versions of a reference clock. The reference clock signal is propagated sequentially through a series of delay stages. Each delay stage introduces a controlled delay, producing phase-shifted output signals. The delay amount is controlled using a baseline control code, which ensures the phases are spaced evenly within a clock cycle.

According to one or more examples, process 300 may include generating a phase error signal based at least in part on a phase difference between at least one of the multiple phase-shifted output signals and the reference clock signal at block 304. Process 300 identifies phase error in the generated phase-shifted output signals. At least some of it might be due to delay mismatch.

According to one or more examples, process 300 may include determining baseline control codes at least partially based on the phase error signal at block 306. The baseline control codes are control codes necessary to adjust the delay stages to compensate for the detected phase error. Baseline control codes define the nominal delay values before applying additional correction. The control codes ensure that, in an ideal scenario, the phase shifts are evenly distributed among the delay stages.

According to one or more examples, process 300 may include modifying the baseline control codes at least partially based on respective adjustment values at block 308. Process 300 applies stored adjustment values (Δ0, Δ1, Δ2, etc.) to fine-tune the delays beyond the baseline control codes. The adjustment values compensate for per-stage variations, ensuring that the final phase differences meet the required precision. In one or more examples, the adjustment values may be added or subtracted from the baseline control codes to further improve phase alignment. By way of specific, non-limiting example, if the baseline control code suggests a 1 ns delay, but historical analysis indicated that DS1 consistently 50 pico-seconds (ps) if too fast, (or −50 ps if too slow), an adjustment value of +50 ps is applied.

According to one or more examples, the method includes providing the adjusted baseline control codes to the respective delay stage to regulate respective delays of respective delay stages at block 310. Here, the corrected delay values are implemented by applying adjusted control codes to each delay stage.

In practice, the process of FIG. 3 may operate iteratively, repeating steps 302 through 310 in a loop until a locked status is achieved (e.g., when the phase error signal indicates alignment within a predetermined threshold). The loop exits upon detecting the locked status, ensuring convergence of the delay adjustments.

In one or more examples, rather than relying exclusively on phase-detector lock codes, the calibration controller 202 additionally reads a real-time system performance metric such as eye-diagram opening, bit-error rate (BER), or power-converter signal-to-noise ratio (SNR)—from a metric register of an on-chip performance monitor (e.g., an eye-width sampler, a BER counter, or an SNR calculator, without limitation). After loading a candidate set of per-stage adjustment values Δ₀ . . . Δ_{N} into the adder/register bank, compensation controller allows the DLL to re-lock, then samples the metric register to obtain a scalar value M. It compares the scaler value M against the best-known metric M₀ (i.e., the highest performance metric observed so far); if M>M₀, it updates M₀:=M and commits the current Δ vector as the new optimal setting (e.g., writes the current Δ vector into the resisters, without limitation). The process repeats—each time potentially raising M₀ to a higher value-until no further improvements are found (e.g., no change in M₀ after N trials) or a maximum iteration count is reached. By iteratively sweeping individual Δᵢ values (or using a gradient-ascent algorithm), the calibration controller converges on a vector of adjustment values (Δvector) that increases end-to-end performance. This example directly optimizes the actual application metric—e.g., reducing unmodeled board-level effects or load variations—and seamlessly leverages the same infrastructure of FDEs discussed for phase-error calibration, above.

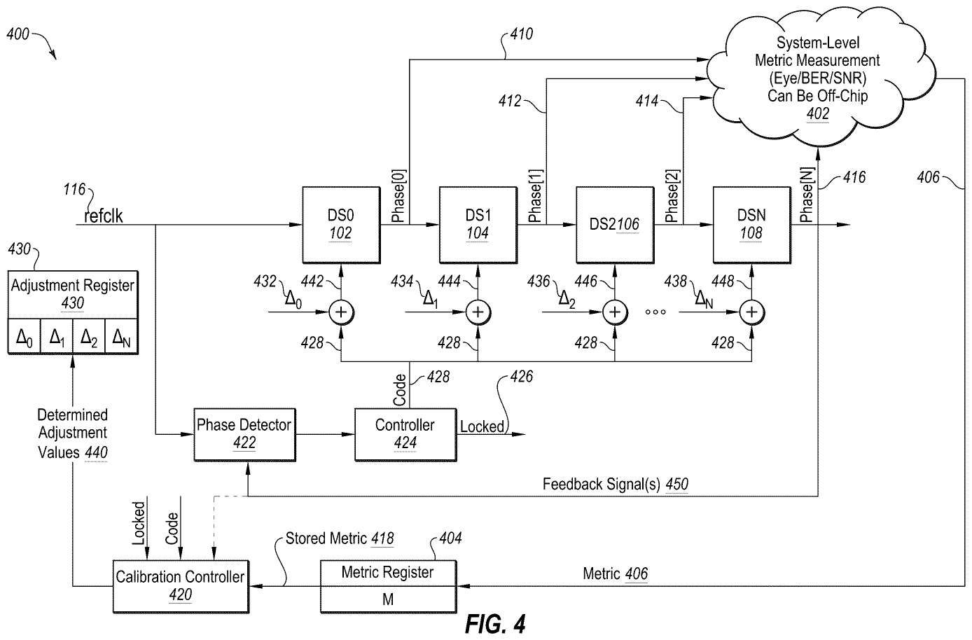

FIG. 4 is a schematic diagram of a DLL system 400 that performs calibration using a system-level performance metric in addition to (or in place of) phase-detector lock codes, in accordance with one or more examples. A chain of delay stages DS0-DSN 102-108 receives a reference clock signal 116 and produces phase-shifted outputs phase[0] to phase[N](individual phases are not labeled with part numbers in FIG. 4 to avoid obscuring the drawing). For each delay stage, a baseline code 428 generated by controller 424 is combined with a respective per-stage adjustment value Δ₀ . . . Δ₃ (per stage adjustment values 432 to 438), which is influenced by a real-time system performance metric as discussed herein, stored in register 430 using per-stage adders. The resultant adjusted baseline control codes 442-448 respectively drive the delay stages to regulate their respective delays. Phase detector 422 compares a selected feedback phase of feedback signal(s) 450 to the reference clock signal 116, and controller 424 asserts a locked indication 426 when the error signal generated by phase detector 422 indicates that the DLL has acquired/re-acquired lock under the presently applied codes.

As mentioned above, calibration controller 420 reads the value of a system-level performance metric 418 and updates (with determined adjustment values 440) the stored per-stage adjustment values at adjustment register 430 to improve (e.g. increase, without limitation) the system-level performance metric. In one or more examples, the metric value is a scalar measurement of the system-level performance metric obtained over a defined measurement interval and stored in the metric register 404.

In one or more examples, calibration controller 420 writes trial Δ-vectors (sets of candidate per-stage adjustment values) to the register 430, allows the DLL to re-lock (as indicated by locked 426 from the phase-detector/controller path), and then evaluates end-to-end performance using the scalar metric value stored at metric register 404. The metric register 404 is written with metric M 406 by performance monitor 402. In one or more examples, performance monitor 402 may compute the metric on-chip (e.g., eye-opening, BER, or SNR, without limitation) by sampling one or more of the phase taps 410 to 416. Alternatively, in one or more examples, performance monitor 402 may receive the metric 406 from off-chip instrumentation and store the received metric 406 at metric register 404.

In one or more examples, the calibration controller 420 compares the current metric M stored at register 404 to a best-known metric M₀; if M is greater than M₀, the controller commits the current Δ-vector as the new “performance improving” setting and updates M₀. If M is not greater than M₀, the calibration controller 420 discards the trial Δ-vector and selects a new perturbation. In one or more examples, the metric 406 from performance monitor 402 may be a scalar metric value, and it may be made available (e.g., exposed by performance monitor 402 to calibration controller 420 via a bus or system level registers, without limitation) to the calibration controller 420. The process iterates—e.g., by coordinate descent on individual Δᵢ or by a gradient-ascent search—until a convergence criterion is met (no improvement after a specified number of trials, a lock-quality dwell time, or a maximum iteration count). This approach directly optimizes the actual application metric while reusing the same fine-delay elements, adders, and registers used for the phase-error-based calibration previously described.

In one or more examples, calibration controller 420 may also read “code-at-lock” information from the controller/phase detector path (depicted by the connections for locked indication 426 and code 428) and combines this code-at-lock information with the metric M when determining adjustment updates (Δ-updates), thereby preserving DLL stability while improving the system-level metric. In various examples, metric-driven updates to adjustments may be solely based on metric updates (e.g., updates to metric 406, without limitation), or based on a hybrid operation in which metric-driven updates to adjustments are constrained by phase-detector lock status.

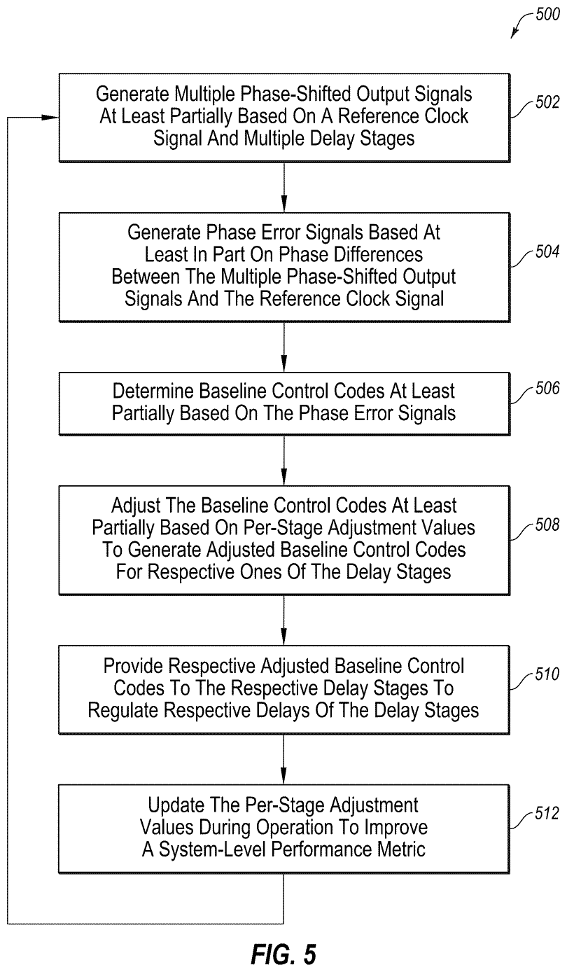

FIG. 5 is a flow diagram of an example process 500 for operating a DLL while updating stored per-stage adjustment values during operation responsive to a system-level performance metric, in accordance with one or more examples. Although the example process 500 depicts a particular sequence of operations, the sequence may be altered without departing from the scope of the present disclosure (e.g., some operations may be performed in parallel or repeated until convergence). Some or a totality of operations of process 500 may be performed, as a non-limiting example, by DLL system 400 of FIG. 4.

According to one or more examples, process 500 may include generating multiple phase-shifted output signals at least partially based on a reference clock signal and multiple delay stages, in operation 502.

According to one or more examples, process 500 may include generating phase error signals based at least in part on phase differences between the multiple phase-shifted output signals and the reference clock signal, in operation 504.

According to one or more examples, process 500 may include determining baseline control codes at least partially based on the phase error signals, in operation 506.

According to one or more examples, process 500 may include adjusting the baseline control codes at least partially based on per-stage adjustment values to generate adjusted baseline control codes for respective ones of the delay stages, in operation 508.

According to one or more examples, process 500 may include providing respective adjusted baseline control codes to the respective delay stages to regulate respective delays of the delay stages, in operation 510.

According to one or more examples, process 500 may include updating the per-stage adjustment values during operation to improve a system-level performance metric, in operation 512.

In one or more examples, this may include reading a scalar metric value M from a metric register written by a performance monitor (e.g., eye-opening, BER, or SNR), and changing one or more stored per-stage adjustment values responsive to the metric value to increase the system-level performance metric while maintaining DLL lock. Updated values are written back to the registers and used in forming the adjusted baseline control codes of block 508. The update may execute periodically, event-driven, or quasi-continuously, and may continue until a convergence criterion is satisfied (e.g., no improvement after a predetermined number of iterations or a predetermined dwell-time-based lock-quality condition), after which the then-stored adjustment values remain for normal operation. In some examples, the metric is computed on-chip; in other examples, an off-chip instrument provides the metric value and it is stored in the metric register.

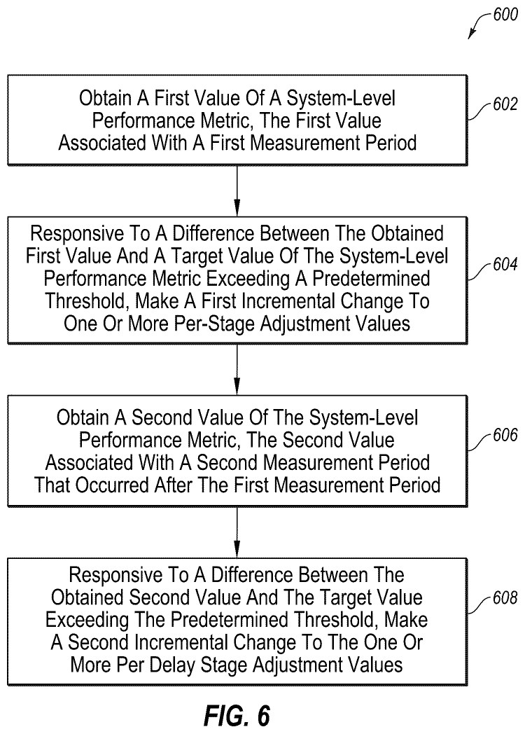

FIG. 6 is a flow diagram of an example process 600 in which incremental changes to one or more stored per-stage adjustment values are made responsive to a difference between a measured metric value and a target value, in accordance with one or more examples. Although the example process 600 depicts a particular sequence of operations, the sequence may be altered without departing from the scope of the present disclosure; some or all operations may be performed by DLL system 400.

According to one or more examples, the method includes obtaining a first value of a system-level performance metric, the first value associated with a first measurement period, at operation 602. The “system-level performance metric” is a chosen criterion (e.g., eye-width, BER, or SNR, without limitation) and the “first value” is a scalar measurement taken over a defined window—optionally after the DLL is allowed to settle in a current operating state (baseline code plus the then-stored per-stage adjustment values). The measurement period of defined the window is long enough to average noise and short enough to permit iterative incremental updates of the adjustment values (e.g., multiple DLL lock intervals, without limitation).

According to one or more examples, process 600 may include, responsive to a difference between the obtained first value and a target value of the system-level performance metric exceeding a predetermined threshold, make a first incremental change to one or more per-stage adjustment values, at operation 604. In one or more examples, the “target value” may be a value that represents a fixed design target or a stored best-known value from prior iterations. The “predetermined threshold” represents a minimum acceptable difference between the measured value of the system-level performance metric and the target value. A “first incremental change” means a small adjustment, such as a single code step (e.g., one fine-delay-element step, without limitation) while constraining the adjustment value within allowable bounds so that loop stability and timing margins are preserved. Direction and delay stage selection may follow an acceptance rule (e.g., coordinate-descent on adjustment value, without limitation) without committing to any specific algorithm, and the system re-enters a settled, locked condition before the next measurement window begins.

According to one or more examples, process 600 may include obtaining a second value of the system-level performance metric, the second value associated with a second measurement period that occurred after the first measurement period, at operation 606. In one or more examples, the second value is associated with a second measurement period where the measurement window is comparable to the measurement window utilized to obtain the first value. Operation 606, as part of the iterative updates described in relation to process 500 (e.g., using gradient-ascent or coordinate descent for convergence), evaluates the impact of the first incremental change by comparing metrics over comparable windows.

According to one or more examples, process 600 may include responsive to a difference between the obtained second value and the target value exceeding the predetermined threshold, make a second incremental change to the one or more per delay stage adjustment values, at operation 608. As an example of the iterative convergence methods discussed earlier (e.g., gradient ascent in relation to FIG. 4 and process 500), if a comparison indicates improvement or sufficient movement toward the target value, the prior change to the adjustment value is retained/committed and another incremental change is applied to one or more adjustment values. If no improvement or insufficient movement, the prior change may be reverted and a different adjustment values (associated with different delay stages) and/or direction may be chosen and utilized. Step size may be adaptive (e.g., reduce when successive windows fail to improve), and updates stop when a convergence criterion is met, leaving the then-stored adjustment values in place for normal operation.

FIG. 6 illustrates an example of the iterative convergence techniques (e.g., gradient ascent) described in relation to FIGS. 4 and 5, where incremental changes are made based on sequential measurements of the system-level performance metric.

It will be appreciated by those of ordinary skill in the art that functional elements of examples disclosed herein (e.g., functions, operations, acts, processes, or methods) may be implemented in any suitable hardware, software, firmware, or combinations thereof. FIG. 4 illustrates non-limiting examples of implementations of functional elements disclosed herein. In some examples, some or all portions of the functional elements disclosed herein may be performed by hardware capable of carrying out the functional elements.

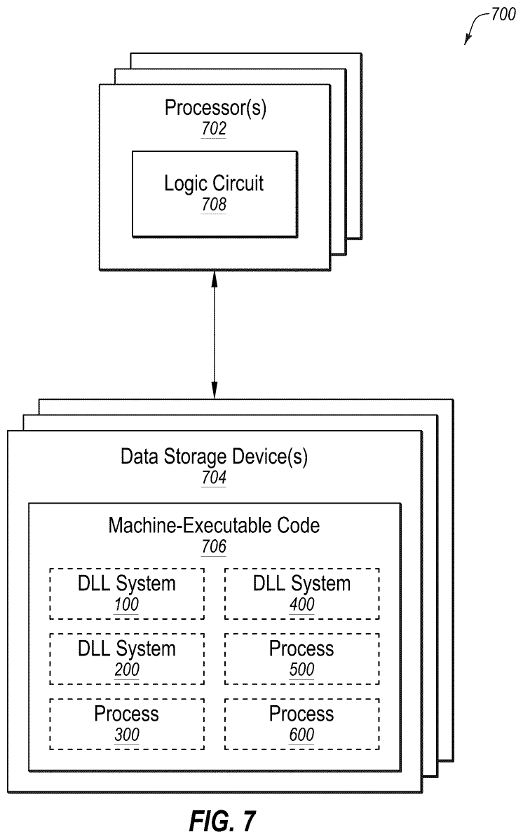

FIG. 7 is a block diagram of a circuitry 700 that, in some examples, may be used to implement various functions, operations, acts, processes, or methods disclosed herein. The circuitry 700 includes one or more processors 702 (sometimes referred to herein as “processors 702”) operably coupled to one or more data storage devices 704 (sometimes referred to herein as “storage 704”). The storage 704 includes machine executable code 706 stored thereon and the processors 702 include logic circuit 708. The machine executable code 706 includes information describing functional elements that may be implemented by (e.g., performed by) the logic circuit 708. The logic circuit 708 is adapted to implement (e.g., perform) the functional elements described by the machine executable code 706. The circuitry 700, when executing the functional elements described by the machine executable code 706, should be considered as special purpose hardware for carrying out functional elements disclosed herein. In one or more examples, the processors 702 may perform the functional elements described by the machine executable code 706 sequentially, concurrently (e.g., on one or more different hardware platforms), or in one or more parallel process streams.

When implemented by logic circuit 708 of the processors 702, the machine executable code 706 adapts the processors 702 to perform operations of examples disclosed herein. By way of non-limiting example, the machine executable code 706 may adapt the processors 702 to perform some or a totality of operations of one or more of: process 300.

Also, by way of non-limiting example, the machine executable code 706 may adapt the processors 702 to perform some or a totality of features, functions, or operations disclosed herein for one or more of: DLL system 100 or DLL system 200. More specifically, features, functions, or operations disclosed herein for one or more of: delay stage 102, a delay stage 104, a delay stage 106, a delay stage 108, a phase detector 110, a controller 112, a register 114, a reference clock signal 116, one or more feedback signals 118, a phase 120, a phase 122, a phase 124, a phase 126, an adjustment value 128, an adjustment value 130, an adjustment value 132, an adjustment value 134, a control code 136, an adjusted control code 138, an adjusted control code 140, an adjusted control code 142, an adjusted control code 144, or a baseline control code 136 of DLL system 100; and calibration controller 202, a multiplexer 204, a selected phase 206, a selection signal 208, a phase detector 210, a controller 212, a baseline control code 214, and a locked status signal 216 of DLL system 200.

The processors 702 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device (PLD), discrete gate or transistor logic, discrete hardware components, other programmable device, or any combination thereof designed to perform the functions disclosed herein. A general-purpose computer including one or more processors 702, including a general-purpose processor, is considered a special-purpose computer at least while the general-purpose computer executes functional elements corresponding to the machine executable code 706 (e.g., software code, firmware code, configuration data, hardware descriptions, without limitation) related to examples of the present disclosure. It is noted that a general-purpose processor (which may also be referred to herein as a host processor or simply a host) may be a microprocessor, but in the alternative, a general-purpose processor of processors 702 may include any conventional processor, controller, microcontroller, or state-machine. An FPGA or other PLD of the processors 702 may be configured (e.g., programmed, without limitation) with configuration data to perform functions disclosed herein, or, additionally or alternatively, may be capable of being configured or re-configured (e.g., programmable or re-programmable, without limitation) with configuration data to perform functions disclosed herein. The processors 702 may also be implemented as a combination of computing devices, such as a combination of a DSP and a microprocessor, a plurality of microprocessors, one or more microprocessors in conjunction with a DSP core, or any other such configuration.

In one or more examples, the storage 70 includes volatile data storage (e.g., random-access memory (RAM), static RAM (SRAM), without limitation), non-volatile data storage (e.g., Flash memory, a hard disc drive, a solid-state drive, erasable programmable read-only memory (EPROM), without limitation). In some examples, the processors 702 and the storage 70 may be implemented into a single device (e.g., a semiconductor device product, a system on chip (SOC), without limitation). In some examples, the processors 702 and the storage 704 may be implemented into separate devices.

In one or more examples, the machine executable code 706 may include computer-readable instructions (e.g., software code, firmware code). By way of non-limiting example, the computer-readable instructions may be stored by the storage 704, accessed directly by the processors 702, and executed by the processors 702 using at least the logic circuit 708. Also, by way of non-limiting example, the computer-readable instructions may be stored on the storage 704, transferred to a memory device (not shown) for execution, and executed by the processors 702 using at least the logic circuit 708. Processors 702 or logic circuit 708 thereof be coupled to such a memory device or include such a memory device (e.g., a configuration memory cell, without limitation). Accordingly, in some examples, the logic circuit 708 includes electrically configurable logic circuit 708.

In one or more examples, the machine executable code 706 may describe hardware (e.g., circuitry) to be implemented in the logic circuit 708 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog, SystemVerilog or very-large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 708 may be described in an RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples, the machine executable code 706 may include an HDL, an RTL, a GL description, a mask level description, other hardware description, or any combination thereof.

In examples where the machine executable code 706 includes a hardware description (at any level of abstraction), a system (not shown, but including the storage 704) implements the hardware description described by the machine executable code 706. By way of non-limiting example, the processors 702 may include a programmable logic device (e.g., an FPGA or a PLC, without limitation), and the logic circuit 708 may be electrically controlled (e.g., via configuration data, without limitation) to implement circuitry corresponding to the hardware description into the logic circuit 708. Also, by way of non-limiting example, the logic circuit 708 may include hard-wired logic manufactured by a manufacturing system (not shown but including the storage 704) according to the hardware description of the machine executable code 706.

Regardless of whether the machine executable code 706 includes computer-readable instructions or a hardware description, the logic circuit 708 is adapted to perform the functional elements described by the machine executable code 706 when implementing the functional elements of the machine executable code 706. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the systems and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different sub-combinations of some of the elements. For example, the phrase “A, B, C, D, or combinations thereof” may refer to any one of A, B, C, or D; the combination of each of A, B, C, and D; and any sub-combination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus, comprising: multiple delay stages coupled in series to sequentially delay a reference clock signal and generate phase-shifted output signals; a phase detector to generate a phase error signal at least partially based on a phase difference between a at least one of the phase-shifted output signals and a reference clock signal; a control circuit to generate baseline control codes to regulate respective phase shifts of respective delay stages; and a compensation circuit to: modify a baseline control code for a respective delay stage at least partially based on a respective stored adjustment value; and provide the adjusted baseline control code to the respective delay stage.

Example 2: The apparatus according to Example 1, wherein the control circuit to evenly distribute the phase difference indicated by the phase error among the baseline control codes generated for the multiple delay stages.

Example 3: The apparatus according to Examples 1 and 2, wherein the compensation circuit includes registers of predetermined adjustment values.

Example 4: The apparatus according to any of Examples 1 to 3, comprising a calibration circuit to: sequentially select different phase-shifted output signals for phase comparison; determine respective adjustment values for each delay stage based on deviations between expected and measured phase differences; and store the adjustment values in a register for use by the compensation circuit.

Example 5: The apparatus according to any of Examples 1 to 4, where the calibration circuit to: iteratively lock the phase detector onto different phase outputs; determines phase differences for each delay stage; determines adjustment values that reduce delay mismatch across the delay stages; and stores the determined adjustment values in a register.

Example 6: The apparatus according to any of Examples 1 to 5, wherein the calibration circuit to sequentially select phase-shifted output signals for comparison by the phase detector.

Example 7: The apparatus according to any of Examples 1 to 6, comprising: a register to store a value indicative of a system-level performance metric; and a calibration circuit to update respective stored adjustment values to increase the system-level performance metric.

Example 8: The apparatus according to any of Examples 1 to 7, wherein the register that stores the value indicative of the system-level performance metric is written by a performance monitor that derives the value from one or more of: eye-diagram width, bit-error rate (BER), or signal-to-noise ratio (SNR).

Example 9: The apparatus according to any of Examples 1 to 8, wherein the register is written by the performance monitor based on measurements by an off-chip measurement equipment.

Example 10: The apparatus according to any of Examples 1 to 9, wherein the register is written by the performance monitor based on measurements by on-chip measurement equipment.

Example 11: A method, comprising: generating multiple phase-shifted output signals at least partially based on a reference clock signal; generating a phase error signal based at least in part on a phase difference between at least one of the multiple phase-shifted output signals and the reference clock signal; determining baseline control codes at least partially based on the phase error signal; modifying the baseline control codes at least partially based on respective adjustment values; and providing the adjusted baseline control codes to a respective delay stage to regulate respective delays of respective delays of respective delays of respective delay stages.

Example 12: The method according to Example 11, comprising: sequentially selecting different phase-shifted output signals for phase comparison; determining respective adjustment values for each delay stage based on deviations between expected and measured phase differences; and storing the adjustment values in a register for use by a compensation circuit.

Example 13: The method according to Examples 11 and 12, comprising: iteratively locking a phase detector onto different phase outputs; determining phase differences for each delay stage; determining adjustment values that reduce delay mismatch across the delay stages; and storing the determined adjustment values in a register.

Example 14: The method according to any of Examples 11 to 13, comprising: evenly distributing the phase difference indicated by the phase error signal among the baseline control codes generated for the multiple delay stages.

Example 15: The method according to any of Examples 11 to 14, wherein generating multiple phase-shifted output signals comprises: sequentially delaying a reference clock signal through a plurality of delay stages; and generating respective ones of the multiple phase-shifted output signals at respective ones of the delay stages.

Example 16: The method according to any of Examples 11 to 15, detecting a phase difference between at least one of the phase-shifted output signals and the reference clock signal.

Example 17: The method according to any of Examples 11 to 16, comprising: storing, in a register, a value indicative of a system-level performance metric; and, during operation, updating respective stored per-stage adjustment values responsive to the value to increase the system-level performance metric.

Example 18: The method according to any of Examples 11 to 17, comprising: deriving a scalar metric value using a performance monitor based on one or more of: eye-diagram width, bit-error rate (BER), or signal-to-noise ratio (SNR), and storing the derived scalar metric value in the register.

Example 19: The method according to any of Examples 11 to 18, wherein deriving the scalar metric value comprises acquiring measurements using off-chip measurement equipment and storing a value indicative of the system-level performance metric in the register.

Example 20: The method according to any of Examples 11 to 19, wherein deriving the scalar metric value comprises acquiring measurements using on-chip measurement equipment and storing a value indicative of the system-level performance metric in the register.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
multiple delay stages coupled in series to sequentially delay a reference clock signal and generate phase-shifted output signals;
a phase detector to generate a phase error signal at least partially based on a phase difference between a at least one of the phase-shifted output signals and a reference clock signal;
a control circuit to generate baseline control codes to regulate respective phase shifts of respective delay stages; and
a compensation circuit to:
modify a baseline control code for a respective delay stage at least partially based on a respective stored adjustment value; and
provide the adjusted baseline control code to the respective delay stage.

2. The apparatus of claim 1, wherein the control circuit to evenly distribute the phase difference indicated by the phase error among the baseline control codes generated for the multiple delay stages.

3. The apparatus of claim 1, wherein the compensation circuit includes registers of predetermined adjustment values.

4. The apparatus of claim 1, comprising a calibration circuit to:
sequentially select different phase-shifted output signals for phase comparison;
determine respective adjustment values for each delay stage based on deviations between expected and measured phase differences; and
store the adjustment values in a register for use by the compensation circuit.

5. The apparatus of claim 4, where the calibration circuit to:
iteratively lock the phase detector onto different phase outputs;
determines phase differences for each delay stage;
determines adjustment values that reduce delay mismatch across the delay stages; and
stores the determined adjustment values in a register.

6. The apparatus of claim 4, wherein the calibration circuit to sequentially select phase-shifted output signals for comparison by the phase detector.

7. The apparatus of claim 1, comprising:
a register to store a value indicative of a system-level performance metric; and
a calibration circuit to update respective stored adjustment values to increase the system-level performance metric.

8. The apparatus of claim 7, wherein the register that stores the value indicative of the system-level performance metric is written by a performance monitor that derives the value from one or more of: eye-diagram width, bit-error rate (BER), or signal-to-noise ratio (SNR).

9. The apparatus of claim 8, wherein the register is written by the performance monitor based on measurements by an off-chip measurement equipment.

10. The apparatus of claim 8, wherein the register is written by the performance monitor based on measurements by on-chip measurement equipment.

11. A method, comprising:
generating multiple phase-shifted output signals at least partially based on a reference clock signal;
generating a phase error signal based at least in part on a phase difference between at least one of the multiple phase-shifted output signals and the reference clock signal;
determining baseline control codes at least partially based on the phase error signal;
modifying the baseline control codes at least partially based on respective adjustment values; and
providing the adjusted baseline control codes to a respective delay stage to regulate respective delays of respective delays of respective delays of respective delay stages.

12. The method of claim 11, comprising:
sequentially selecting different phase-shifted output signals for phase comparison;
determining respective adjustment values for each delay stage based on deviations between expected and measured phase differences; and
storing the adjustment values in a register for use by a compensation circuit.

13. The method of claim 12, comprising:
iteratively locking a phase detector onto different phase outputs;
determining phase differences for each delay stage;
determining adjustment values that reduce delay mismatch across the delay stages; and
storing the determined adjustment values in a register.

14. The method of claim 11, comprising: evenly distributing the phase difference indicated by the phase error signal among the baseline control codes generated for the multiple delay stages.

15. The method of claim 11, wherein generating multiple phase-shifted output signals comprises:
sequentially delaying a reference clock signal through a plurality of delay stages; and
generating respective ones of the multiple phase-shifted output signals at respective ones of the delay stages.

16. The method of claim 11, detecting a phase difference between at least one of the phase-shifted output signals and the reference clock signal.

17. The method of claim 11, comprising: storing, in a register, a value indicative of a system-level performance metric; and, during operation, updating respective stored per-stage adjustment values responsive to the value to increase the system-level performance metric.

18. The method of claim 17, comprising: deriving a scalar metric value using a performance monitor based on one or more of: eye-diagram width, bit-error rate (BER), or signal-to-noise ratio (SNR), and storing the derived scalar metric value in the register.

19. The method of claim 18, wherein deriving the scalar metric value comprises acquiring measurements using off-chip measurement equipment and storing a value indicative of the system-level performance metric in the register.

20. The method of claim 18, wherein deriving the scalar metric value comprises acquiring measurements using on-chip measurement equipment and storing a value indicative of the system-level performance metric in the register.
